(19) United States
(12) Patent Application Publication
(10) Pub. No.: US 2025/0052512 A1
(43) Pub. Date: Feb. 13, 2025

(54) MULTI-SECTIONAL VAPOR CHAMBERS

(71) Applicant: Intel Corporation, Santa Clara, CA (US)

(72) Inventors: Shantanu Kulkarni, Hillsboro, OR (US); Jeff Ku, Taipei (TW); Baomin Liu, Hillsboro, OR (US); Tongyan Zhai, Portland, OR (US); Min Suet Lim, Gelugor (MY); Chee Chun Yee, Bayan Lepas (MY); Eng Huat Goh, Paya Terubong (MY); Jun Liao, Portland, OR (US); Kavitha Nagarajan, Bangalore (IN)

(21) Appl. No.: 18/447,951

(22) Filed: Aug. 10, 2023

(51) Int. Cl. F28D 15/04

(52) U.S. Cl. CPC F28D 15/04

(57) ABSTRACT

Systems, apparatus, articles of manufacture, and methods related to multi-sectional vapor chambers for electronic devices are disclosed. An example vapor chamber includes a first panel, a second panel, and a wall extending between the first panel and the second panel to separate the vapor chamber into a first section and a second section between both the first panel and the second panel, the wall including insulation.

### FIELD OF THE DISCLOSURE

This disclosure relates generally to thermal solutions for electronic devices and, more particularly, to multi-sectional vapor chambers.

### BACKGROUND

Electronic devices use thermal solutions to dissipate heat from heat generating components. Often multiple heat generating components are thermally coupled to a single thermal solution.

### BRIEF DESCRIPTION OF THE DRAWINGS

FIG. 1 is a cross-sectional view of a portion of an example electronic device with an example multi-sectional vapor chamber.

FIG. 2 is a heat map of the example electronic device of FIG. 1.

FIG. 3 is an illustration of an example multi-sectional vapor chamber that may be used to implement the multi-sectional vapor chamber of FIG. 1.

FIG. 4 is an illustration of another example multi-sectional vapor chamber that may be used to implement the multi-sectional vapor chamber of FIG. 1.

FIG. 5 is a perspective view of a portion of an example electronic device with example fencing between example vapor chambers.

FIG. 6 is a top view of the portion of the electronic device of FIG. 5.

FIG. 7 is an exploded view of the portion of the electronic device of FIG. 5.

FIG. 8 a cross-sectional of the portion of the electronic device of FIG. 5 taken along the A-A line of FIG. 6.

FIG. 9 is an enlarged view of the encircled area B of FIG. 5.

FIG. 10 shows example airflow through the portion of the electronic device of FIG. 5.

FIG. 11 is an enlarged view of the encircled area C of FIG. 10.

FIG. 12 a cross-sectional of the portion of the electronic device of FIG. 5 taken along the D-D line of FIG. 10.

FIG. 13 is a flowchart representative of example machine readable instructions and/or example operations that may be executed, instantiated, and/or performed by example programmable circuitry to form a multi-sectional vapor chamber.

FIG. 14 is a block diagram of an example processing platform including programmable circuitry structured to execute, instantiate, and/or perform the example machine readable instructions and/or perform the example operations of FIG. 13.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Electronic devices such as, for example, laptop computers include printed circuit boards (PCBs) that are loaded with multiple heat generating components such as, for example, integrated circuits (ICs), central processing units (CPUs), memory, graphics processing units (GPUs), a vision processing unit (VPU), voltage regulators (VRs), solid state drives (SSDs), etc. In some example electronic devices these heat generating components are in the vicinity of each other. In some examples, these heat generating components dissipate different amounts of heat and have different temperature limits before their performance is compromised.

In some electronic devices, many of the heat generating components are coupled to a single thermal solution. This approach is to minimize board holes, reduce number of parts, and simplify assembly and mounting of the components of the electronic device. The thermal solution can include, for example, a vapor chamber, a heat sink, heat spreader, a heat pipe, and/or a fan, etc.

When the heat generating components are positioned in close proximity, there may be thermal crosstalk between the heat generating components. That is, heat from one heat generating component may warm another heat generating component as the heat spreads through the thermal solution. This leads to components having lower temperature threshold limits reaching the temperature limit sooner and impacting or degrading system performance. Consider, for example, a PCB including a graphics double data rate (GDDR) memory proximate to a GPU. In this example, the GDDR and the GPU are coupled through a vapor chamber (VC) as the thermal solution to dissipate heat generated by the GDDR and GPU. The GDDR may have a temperature limit of 80° Celsius (C), beyond which performance of the GDDR degrades. Heat bleeding over through the VC from the GPU may cause the GDDR to exceed the GDDR temperature limit and reach, for example, 100° C. When the temperature limit is exceeded, the GDDR is operating at a stress workload. To reduce the temperature so the GDDR can operate at or under the 80° C. temperature limit, the GPU power can be throttled, which results in reduced performance of the GPU. In another example, a voltage regulator (VR) with a temperature limit of 120° C. that shares a thermal solution with a CPU may need to operate a lower power level to cool the VR (e.g., to 90° C.) so that the CPU does not exceed its temperature limit.

Examples disclosed herein include thermal solutions that lead to better system performance than conventional designs that have multiple heat generating components coupled to a single, undivided vapor chamber. Examples disclosed herein include a vapor chamber with multiple sections separated by insulating material, which may be implemented as a network of walls. In some examples, respective sections of the multiple sections of the vapor chamber may incorporate different types of wick structures and/or different working fluids. In some examples, different sections of the vapor chamber provide different thermal cooling capacities or capabilities to different sets of heat generating components on the PCB based on the respective temperature limits of the heat generating components. In some examples, different wick structures and liquids allow usage of high-performance wicks and liquids to be reserved for areas of high power dissipation and lower temperature limits (e.g., at the CPU) rather than throughout the entire thermal solution. Also, in some examples, the vacuum levels in different sections of the vapor chamber can be set differently depending on the properties of the working liquids. The differentiation and specialization of the wick structures, working fluids, and/or vacuum levels allows for cost and/or structural optimization of the vapor chamber.

In some examples, the network of insulating material or insulator network is designed and implemented to create a spreading area to match or complement the temperature limits and power consumption for different heat generating components. A spreading area is the area of a vapor chamber across which heat from a heat generating component dissipates. In some examples, the insulator network made from a plastic material and is designed to create enough area to provide cooling for different sources while at the same time reducing thermal crosstalk and temperature influence among the neighboring spreading areas for neighboring sections of the vapor chamber. In some examples, lines of the insulator network lines extend to the edges of the vapor chamber to isolate different areas of spreading.

In some examples disclosed herein, there is a single construction of the vapor chamber having one top panel and one bottom panel in which there is a framework (e.g., the insulation network) to provide the multi-sectional vapor chamber. The single construction provides simplicity in assembly and mounting of the vapor chamber in the electronic device. In addition, the single construction of the vapor chamber has less impact on the board space of the PCB because additional holes are not needed to mount complex structure to the PCB.

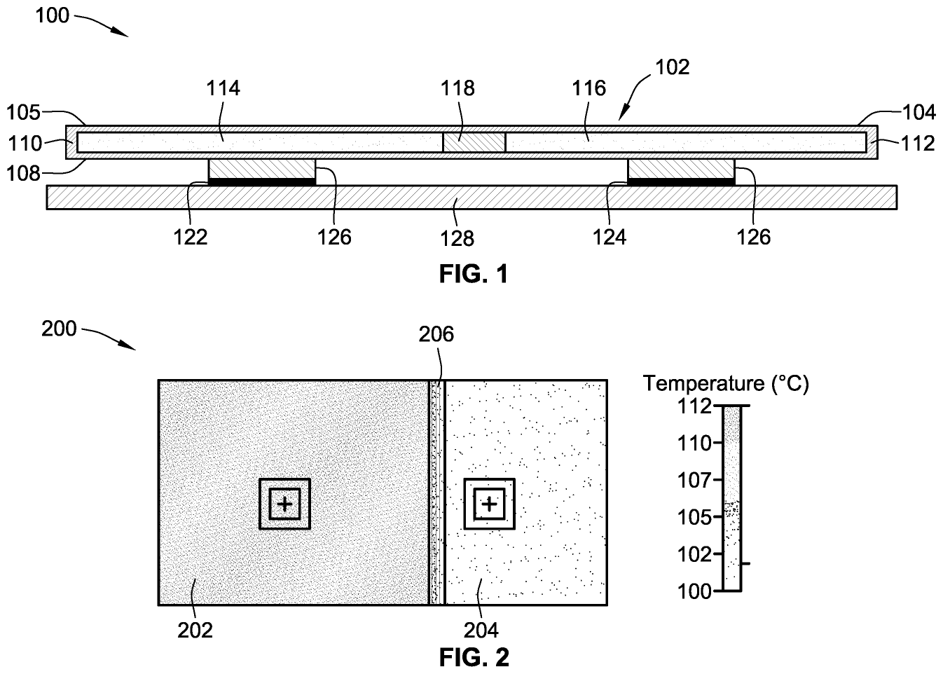

FIG. 1 is a cross-sectional view of a portion of an example electronic device 100 with an example multi-sectional vapor chamber 102. The vapor chamber 102 includes an example perimeter wall 104. The perimeter wall 104 includes an example first panel or top panel 106, an example second panel or bottom panel 108, and example first side panel 110, and an example second side panel 112. The perimeter wall 104 envelops or encloses an example first vapor chamber section 114 and an example second vapor chamber section 116. The first vapor chamber section 106 and the second vapor chamber section 108 are separated by an example wall 118 that is enclosed within the perimeter wall 104. The perimeter wall 104 creates an integral structure containing the multi-sectional vapor chamber 102.

In the illustrated example, the wall 118 is an insulator. Thus, the wall 118 may be referred to as an insulation wall or thermal insulation law. In some examples, the wall 118 includes plastic. In some examples, the wall 118 includes an evacuated or vacuumed tube. In some examples, the wall 118 is part of a network of walls forming an insulation network that divides the multi-sectional vapor chamber 102 into a plurality of sections.

In some examples, the multi-sectional vapor chamber 102 has dimensions of 100 millimeters (mm)×200 mm×1 mm. In some examples, the perimeter wall 104 has a thickness of 0.1 mm. In some examples, the perimeter wall 104 includes a metal such as, for example pure copper. In some examples, the wall 118 is 7 mm wide. In other examples, other values and/or materials may be used for these components.

The first vapor chamber section 114 includes an example first wicking structure, and the second vapor chamber section 116 includes an example second wicking structure. Wicking structures include, for example, mesh, sintered powder, grooves, capillaries, and/or fibers, etc. In some examples, the first wicking structure and the second wicking structure are the same type of wicking structure, and in other examples, the second wicking structure is different than the first wicking structure. In some examples, the first wicking structure and/or the second wicking structure includes a wick material modeled with 15 kilowatt/square meter Kelvin (kW/m²K).

In some examples, the first vapor chamber section 114 includes an example first working fluid, and the second vapor chamber section 116 includes an example second working fluid. Working fluids include, for example, water, methyl alcohol, propylene glycol, and different combination thereof. In some examples, the first working fluid and the second working fluid are the same type of working fluid, and in other examples, the second working fluid is different than the first working fluid.

The multi-sectional vapor chamber 102 is coupled to an example first heating generating source or component 120 and an example second heat generating source or component 122. In some examples, the multi-sectional vapor chamber 102 is coupled to the example first heat generating component 120 and the second heat generating component 122 via respective example pedestals 126. In some examples, the pedestals include a metal such as, for example, copper. In some examples, the pedestals are 0.5 mm thick. The first heat generating component 120 and the second heat generating component 122 are mounted to an example PCB 128.

The first heat generating component 120 and the second heat generating component 122 consume a different amount of power, generate different amount of heat, and have different temperature threshold limitations. For example, the first heat generating component 120 may operate at 25 Watts (W) with a temperature limit of 115° C. In this example, the second heat generating component 122 may operate at 5 W with a temperature limit of 105° C. The wall 118 thermally separates or isolates the first vapor chamber section 114 and the second vapor chamber section 116. The first heat generating component 120 is thermally coupled to the first vapor chamber section 114, and the second heat generating component 122 is thermally coupled to the second vapor chamber section 116. Thus, the wall 118 also thermally separates or isolates the first heat generating component 120 and the second heat generating component 122.

FIG. 2 is an example heat map 200 of the portion of the electronic device 100 of FIG. 1 with the multi-sectional vapor chamber 102. The heat map 200 shows that the first vapor chamber section 114 creates an example first spreading area 202 across which heat from the first heat generating component 120 dissipates. The second vapor chamber section 116 creates an example second spreading area 204 across which heat from the second heat generating component 122 dissipates. Continuing with the example described above, the temperature in the first spreading area 202 is 112° C., which is below the temperature limit of 115° C. for the first heat generating component 120. The temperature in the second spreading area 204 is 102° C., in this example, which is below the temperature limit of 105° C. for the second heat generating component 122. The temperature in a border area 206 is, in this example, about 105-106° C. The border area 206 corresponds to the position of the wall 118 in the multi-section vapor chamber 102.

The wall 118 prevents, inhibits, or impedes thermal crosstalk or heat exchange between the first heat generating component 120 and the second heat generating component 122. In other words, the wall 118 prevents heat from the first heat generating component 120 from overheating the second heat generating component 122 and pushing the second heat generating component 122 past its temperature limit. In conventional vapor chambers, without the wall 118, there would be thermal bleed across the vapor chamber caused by heat generated by the heat generating components that would result in a common temperature across the vapor chamber and heat generating components. In these conventional designs, the common temperature, if hotter than the temperature limit of one of the heat generating components, would increase the risk of failure of such heat generating component. In the examples disclosed herein, the multi-sectional vapor chamber 102 maintains the first heat generating component 120 and the second heat generating component 122 within their temperature limits. The multi-sectional vapor chamber 102 accomplishes this thermal separation even with a perimeter wall 104 constructed of metal, despite the thermal conduction that occurs through metal.

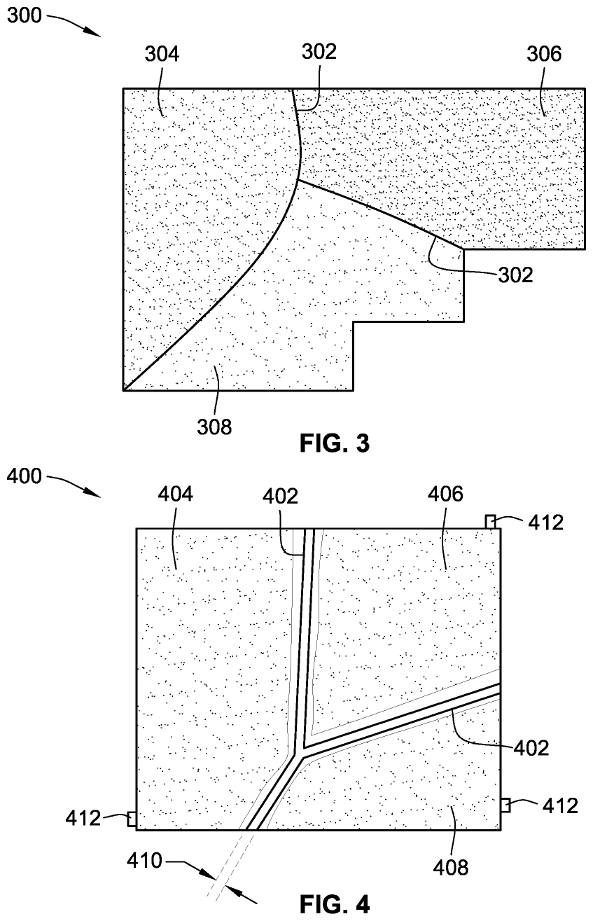

FIG. 3 is an illustration of a portion of an example multi-sectional vapor chamber 300 that may be used to implement the multi-sectional vapor chamber 102 of FIG. 1. The multi-sectional vapor chamber 102 of FIG. 1 included the wall 118, which is linear. The multi-sectional vapor chamber 300 of FIG. 3 includes an example network of walls 302 that separate the multi-sectional vapor chamber 300 into a plurality of sections. In the example of FIG. 3, the network of walls 302 separates the multi-sectional vapor chamber 300 into an example first vapor chamber section 304, an example second vapor chamber section 306, and an example third vapor chamber section 308. The network of walls 302 include curved walls and/or a combination of curved and straight walls. The network of walls 302 can divide the multi-sectional vapor chamber 300 into a plurality of sections that have different surface area, different shapes, and/or different sizes. In the illustrated example, the network of walls 302 includes two walls and, in other example, there may be other numbers of walls such as three, four, five, etc. The positions, shape, and length of the walls of the network of walls 302, and thus, the respective sizes of the first vapor chamber section 304, the second vapor chamber section 306, and the third vapor chamber section 308 are based on the operating parameters and temperature limits of the heat generating components that are thermally coupled or that are to be thermally coupled to the respective the first vapor chamber section 304, the second vapor chamber section 306, and/or the third vapor chamber section 308.

Different ones of the first vapor chamber section 304, the second vapor chamber section 306, and/or the third vapor chamber section 308 can include different types or amounts of wicking structures, different types or amounts of working fluids, and/or different vacuum parameters to provide different cooling capabilities for the respective one of the first vapor chamber section 304, the second vapor chamber section 306, and/or the third vapor chamber section 308. For example, the first vapor chamber section 302 may include a first wicking structure and a first working fluid. In this example, the second vapor chamber section 304 may include the first wicking structure or a second wicking structure, no working fluid (i.e., a dry wicking structure), and be under a vacuum. Also, in this example the third vapor chamber section 306 may be of solid metal (e.g., copper) and may not include a wicking structure or a working fluid. In some examples, the first vapor chamber section 304 provides increased heat spreading relative to the second vapor chamber section 306 and the third vapor chamber section 308. In some examples, the first vapor chamber section 304 may be suited for a heat generating component such as a CPU or GPU. In some examples, the second vapor chamber section 306 provides thermal spreading and performs an insulation function. In some examples, the third vapor chamber section 308 also provides thermal spreading while also enhancing structural support.

FIG. 4 is an illustration of another example multi-sectional vapor chamber 400 that may be used to implement the multi-sectional vapor chamber 102 of FIG. 1. Similar to the multi-sectional vapor chamber 300 of FIG. 3, the multi-sectional vapor chamber 400 includes an example network of walls 402 that separate the multi-sectional vapor chamber 400 into a plurality of sections. In the example of FIG. 4, the network of walls 402 separates the multi-sectional vapor chamber 400 into an example first vapor chamber section 404, an example second vapor chamber section 406, and an example third vapor chamber section 408. The network of walls 402 divides the multi-sectional vapor chamber 400 into a plurality of sections that have different surface area, different shapes, and/or different sizes. In the illustrated example, the network of walls 402 includes three walls and, in other example, there may be other numbers of walls such as two, four, five, etc. The positions, shape, and length of the walls of the network of walls 402, and thus, the respective sizes of the first vapor chamber section 404, the second vapor chamber section 406, and the third vapor chamber section 408 are based on the operating parameters and temperature limits of the heat generating components that are thermally coupled or that are to be thermally coupled to the respective the first vapor chamber section 404, the second vapor chamber section 406, and/or the third vapor chamber section 408.

In the example of FIG. 4, the network of walls 402 may include walls that are made from plastic, walls that are evacuated or vacuumed plastic tubes, and/or walls made of metal (e.g., thin copper walls) that are separated a distance such that there is a gap 410 between the walls with nothing in between. The gap 410 between the walls 402 may be under a vacuum. The network of walls 402 thermally separates the first vapor chamber section 404, the second vapor chamber section 406, and the third vapor chamber section 408. The thickness of the walls in the network of walls 402 and/or the width of the gap 410 may be based on the operating power consumption and temperature limits of the heat generating components that are coupled or are to be coupled to respective ones of the first vapor chamber section 404, the second vapor chamber section 406, and/or the third vapor chamber section 408.

Different ones of the first vapor chamber section 404, the second vapor chamber section 406, and/or the third vapor chamber section 408 can include different types or amounts of wicking structures, different types or amounts of working fluids, and/or different vacuum parameters to provide different cooling capabilities for respective ones of the first vapor chamber section 404, the second vapor chamber section 406, and/or the third vapor chamber section 408. For example, the first vapor chamber section 402 may include a first wicking structure and a first working fluid. In this example, the second vapor chamber section 404 may include a second structure and a second working fluid. In this example the third vapor chamber section 406 may include a third wicking structure and a third working fluid.

The multi-sectional vapor chamber 400 also includes an example suction point 412 for respective ones of the first vapor chamber section 404, the second vapor chamber section 406, and/or the third vapor chamber section 408. The suction point 412 is used to control the working fluid in the respective one of the first vapor chamber section 404, the second vapor chamber section 406, and/or the third vapor chamber section 408. The suction point 412 allows the addition or removal of working fluid, which allows for different charge ratios and different partial pressures. A charge ratio is a volume ratio of the working fluid and the overall internal space of the vapor chamber (including the void space of any wicking structure). Partial pressure can also be used to control phase transition of the working fluid based on the heat source for the respective vapor chamber section. Through the suction point 412, the charge ratio can be varied to adjust the thermal resistance of the respective vapor chamber section.

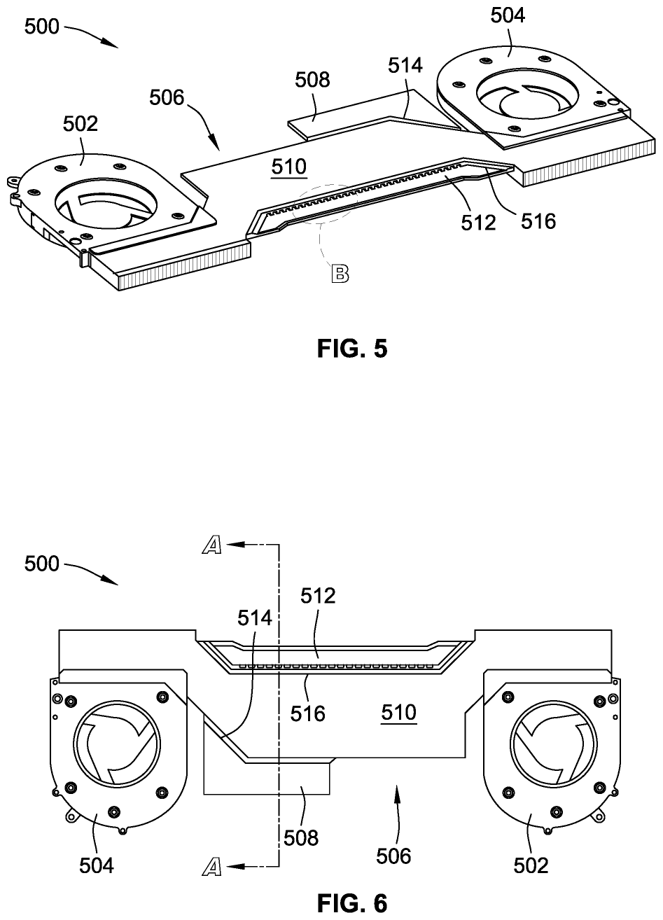

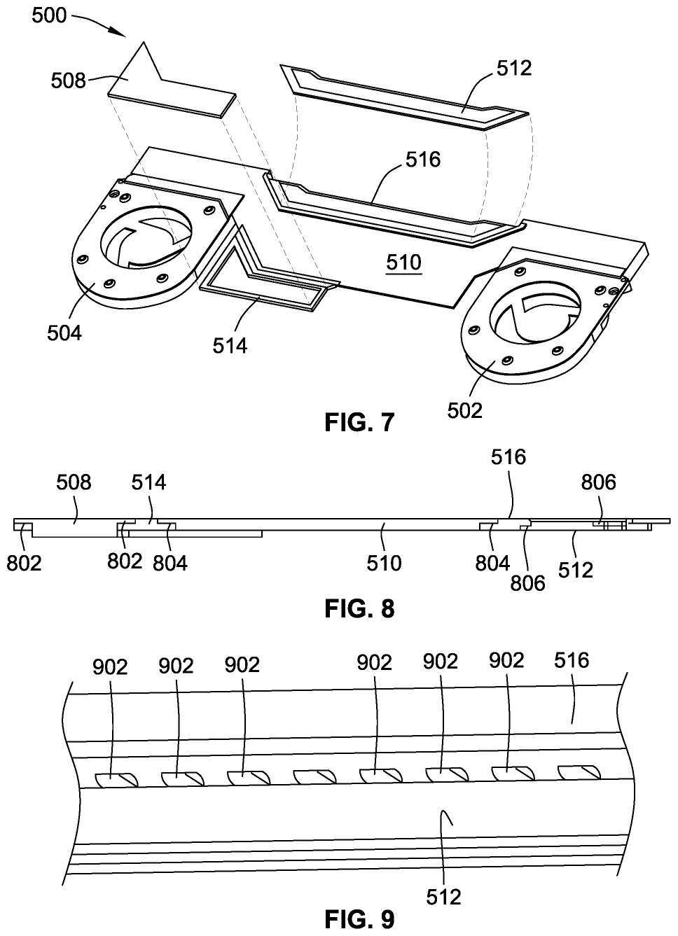

FIG. 5 is a perspective view of a portion of an example electronic device 500. FIG. 6 is a top view of the portion of the electronic device of FIG. 5, FIG. 7 is an exploded view of the portion of the electronic device of FIG. 5, and FIG. 8 a cross-sectional of the portion of the electronic device of FIG. 5 taken along the A-A line of FIG. 6. The portion of the electronic device 500 shown in FIG. 5 is a thermal solution that includes an example first fan 502, an example second fan 504, and an example cluster of vapor chambers that forms an example multi-sectional vapor chamber 506. In the illustrated example, the multi-sectional vapor chamber 506 includes an example first vapor chamber that forms an example first vapor chamber section 508, an example second vapor chamber that forms an example second vapor chamber section 510, and an example third vapor chamber that form an example third vapor chamber section 512. In other examples, the multi-sectional vapor chamber 506 may include other numbers of vapor chambers forming vapor chamber sections such as, for example, two, four, five, etc. In some examples, one or more of the first vapor chamber section 508, the second vapor chamber section 510, and the third vapor chamber section 512 may itself be a multi-sectional vapor chamber such as, for example, one of the multi-sectional vapor chambers 102, 300, 400 disclosed above.

As shown in FIGS. 5-8, the first vapor chamber section 508, the second vapor chamber section 510, and the third vapor chamber section 512 have different shapes, surface areas, thicknesses, wicking structures, working fluids, and/or vacuum parameters. The different thickness may account for different heights of the heat generating components that are coupled to or to be coupled to the respective ones of the first vapor chamber section 508, the second vapor chamber section 510, and/or the third vapor chamber section 512.

In some examples, the first vapor chamber section 508 has a thickness of about 2.5 mm and is used to cool heating generating components such as, for example, video RAM (VRAM). In some examples, the second vapor chamber section 510 has a thickness of about 1.5 mm and is used to cool heating generating components such as, for example, a CPU, a GPU, etc. In some examples, the third vapor chamber section 512 has a thickness of about 1.2 mm and is used to cool heating generating components such as, for example, inductors, metal-oxide-semiconductor field-effect transistors (MOSFETs), etc. In this example, the thickness of the first vapor chamber section 508 is greater than the thickness of the second vapor chamber section 510 because the surface area of the first chamber section 508 is smaller than the surface area of the second vapor chamber section 510. Thus, there is a great maximum power (e.g., of the VRAM) over the smaller area of the first vapor chamber section 508 than that of the larger surface area of the second vapor chamber section 510.

The multi-sectional vapor chamber 506 includes an example first insulation fence 514 that couples the first vapor chamber section 508 and the second vapor chamber section 510. The multi-sectional vapor chamber 506 also includes an example second insulation fence 516 that couples that second vapor chamber section 510 and the third vapor chamber section 512. The first insulation fence 514 and the second insulation fence 516 thermally separate or isolate the first vapor chamber section 508, the second vapor chamber section 510, and the third vapor chamber section 512 to reduce, prevent, inhibit, and/or impede thermal bleed or crosstalk thereamong. In some examples, the first insulation fence 514 and the second insulation fence 516 are created by insert molding on the sealing surfaces of the respective first vapor chamber section 508, second vapor chamber section 510, and/or third vapor chamber section 512.

The sealing surfaces are positioned to face upward or downward so that the overall thickness of the multi-sectional vapor chamber 506 does not increase. For example, as shown in FIG. 8, the example first sealing surfaces 802 of the first vapor chamber section 508 face downward. Example second sealing surfaces 804 of the second vapor chamber section 510 also face downward in this example. In addition, example third sealing surfaces 806 of the third vapor chamber section 512 face upward in this example.

There is flexibility with the modularity of the multi-sectional vapor chamber 506 based on the insert-molded insulation fences (the first insulation fence 514 and the second insulation fence 516) and the vapor chamber cluster (forming the first vapor chamber section 508, second vapor chamber section 510, and third vapor chamber section 512). Different combinations of fences and/or vapor chamber sections can be combined based on the power consumption and temperature limits of the heat generating components.

Furthermore, the thermal solution of the electronic device 500 may be enhanced by perforating the first insulation fence 514 and/or the second insulation fence 516. As shown in FIG. 9, which is an enlarged view of the encircled area B of FIG. 5, the second insulation fence includes a plurality of apertures 902. The apertures 902 act as air ducts and allow air from the first fan 502 and/or the second fan 504 to flow above and below the third vapor changer section 512. In some example systems such as hyperbaric designs, flow impedance within the electronic device affects skin temperature. Increased flow impedance increases skin temperatures. The apertures 902 reduce flow impedance and, therefore, improve (e.g., reduce) skin temperature.

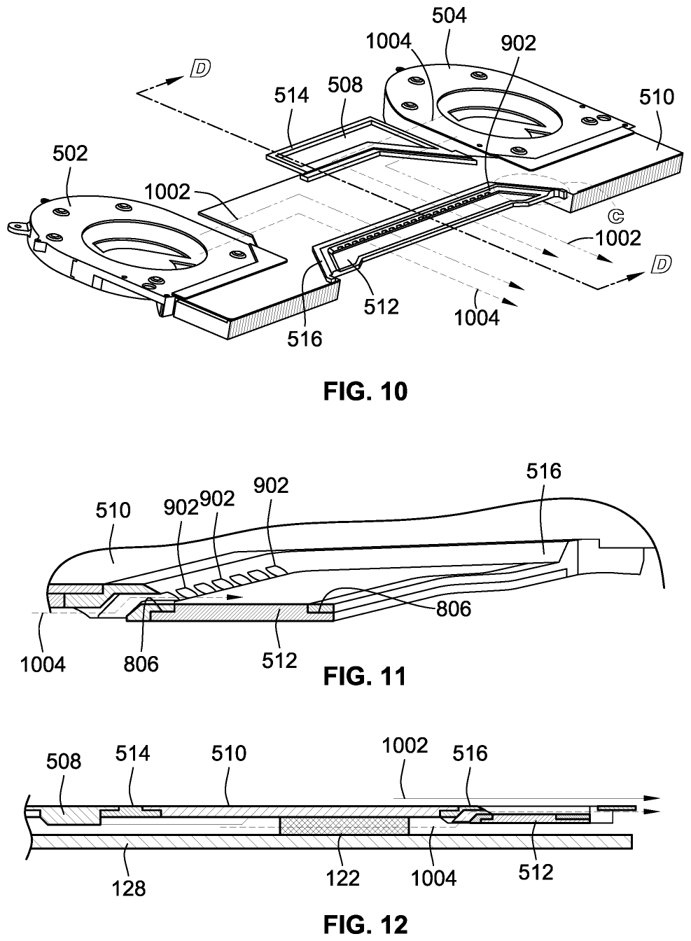

The airflow through the electronic device 500 is shown in FIGS. 10-12. FIG. 10 shows example airflow through the portion of the electronic device of FIG. 5. The arrows 1002 represent the airflow over the top of the multi-sectional vapor chamber 506. The arrows 1004 represent airflow across the bottom of the multi-sectional vapor chamber 506. As shown in FIG. 11, which is an enlarged view of the encircled area C of FIG. 10, the airflow across the bottom of the multi-sectional vapor chamber 506 (arrow 1004) flow through the second insulation fence 516 and out the apertures 902 over the third vapor chamber section 512. In this example, the third vapor chamber section 512 is thinned (e.g., 1.2 mm) to further reduce flow impedance. In addition, in some examples, the third vapor chamber section 512 is at a different altitude than the second vapor chamber section 510 to further reduce flow impedance. In other words, the third vapor chamber section 512 is at a first height and the second vapor chamber section 510 is at a second height, different than the first height.

FIG. 12 a cross-sectional of the portion of the electronic device of FIG. 5 taken along the D-D line of FIG. 10. The airflow across the bottom of the multi-sectional vapor chamber 506 (arrow 1004) flows between the multi-sectional vapor chamber 506 and the PCB 128, over the heat generating component 122 (e.g., a CPU) and through the apertures 902. Thus, the airflow can move between layers of the electronic device 500 to help effectively cool the electronic device 500.

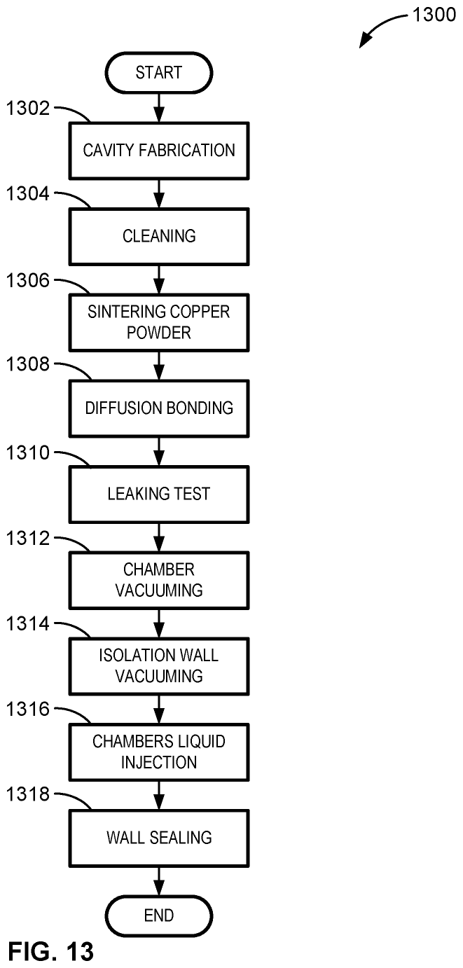

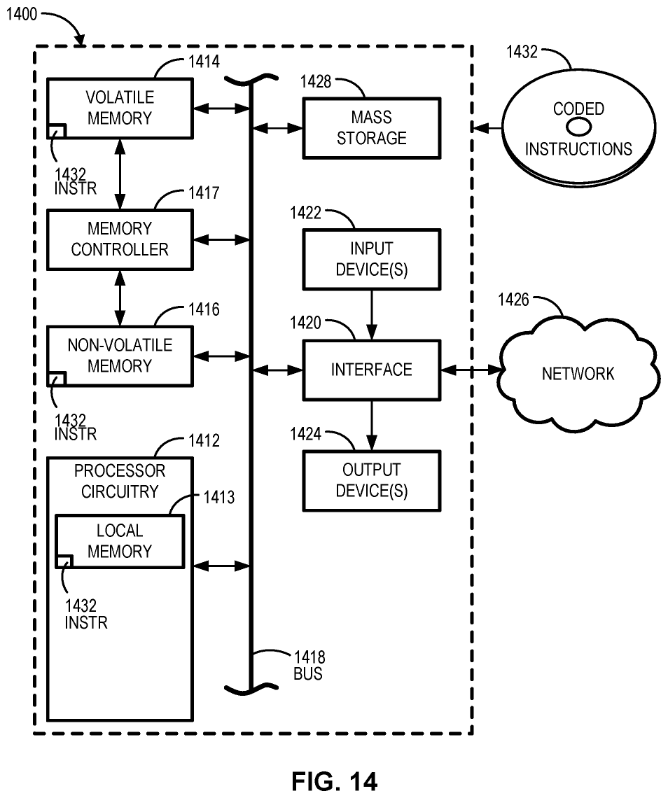

FIG. 13 is a flowchart representative of example operations 1300 that may be executed and/or performed to form a multi-sectional vapor chamber such as, for example, one or more of the multi-sectional vapor chambers 102, 300, 400, disclosed herein. In some examples, the example operations 1300 include example machine readable instructions that may be executed, instantiated, and/or performed by example programmable circuitry such as, for example, by the example processor circuitry 1412 shown in the example processor platform 1400 discussed below in connection with FIG. 14. In other words, in some examples, the processor circuitry 1412 performs the operations 1300 by executing machine readable instructions to cause one or more actuators, robots, and/or other devices to effect the operations 1300. In some examples, the machine-readable instructions cause an operation, a task, etc., to be carried out and/or performed in an automated manner in the real world. As used herein, “automated” means without human involvement.

The example operations 1300 may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 13, many other methods of forming the one or more of the multi-sectional vapor chambers 102, 300, 400 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an application specific circuit (ASIC), a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine readable, computer readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C #, Perl, Python, JavaScript, HyperText Markup Language (HTML), Structured Query Language (SQL), Swift, etc.

As mentioned above, the example operations of FIG. 13 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

The example operations 1300 of FIG. 13 include fabricating a cavity in a substrate of a vapor chamber (block 1302). For example, walls for vacuum isolation can be created that can have varying thicknesses and gap widths. These walls may correspond, for example, to the wall 118 and/or the network of walls 302, 402. In some examples, the fabricating of the cavity includes inserting and/or forming an evacuated or vacuumed tube in the walls of the network of walls.

The operations 1300 also include cleaning the sections (e.g., sections 114, 116, 304, 306, 308, 404, 406, 408) of the vapor chamber (e.g., 102, 300, 400) and the wall (e.g., 118) and/or network of walls (e.g., 302, 402) (block 1304). The sections of the vapor chamber are formed by sintering, for example, copper power (block 1306) and diffusion bonding to join the metal components (block 1308).

The operations 1300 include performing a leaking test (block 1310) to verify that the sections and walls do not leak. The chambers (e.g., the sections of the vapor chamber) are vacuumed (block 1312). The walls that isolate the chambers also are vacuumed (block 1314). The chambers (e.g., the sections of the vapor chamber) are filled with a working fluid (block 1316). For example, the chambers are filled via the suction point 412. The walls are sealed (block 1318), and the example operations 1300 end.

FIG. 14 is a block diagram of an example programmable circuitry platform 1400 structured to execute and/or instantiate the example machine-readable instructions and/or the example operations of FIG. 13. The programmable circuitry platform 1400 can be, for example, a server, a personal computer, a workstation, a self-learning machine (e.g., a neural network), a mobile device (e.g., a cell phone, a smart phone, a tablet such as an iPad™), an Internet appliance, or any other type of computing and/or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAS, microprocessors, CPUs, GPUs, Digital Signal Processors (DSPs), and/or microcontrollers from any desired family or manufacturer. The programmable circuitry 1412 may be implemented by one or more semiconductor based (e.g., silicon based) devices.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1416 may be implemented by flash memory and/or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1422 are connected to the interface circuitry 1420. The input device(s) 1422 permit(s) a user (e.g., a human user, a machine user, etc.) to enter data and/or commands into the programmable circuitry 1412. The input device(s) 1422 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1424 are also connected to the interface circuitry 1420 of the illustrated example. The output device(s) 1424 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1420 of the illustrated example, thus, typically includes a graphics driver card, a graphics driver chip, and/or graphics processor circuitry such as a GPU.

The interface circuitry 1420 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-site wireless system, a line-of-site wireless system, a cellular telephone system, an optical connection, etc.

The programmable circuitry platform 1400 of the illustrated example also includes one or more mass storage discs or devices 1428 to store firmware, software, and/or data. Examples of such mass storage discs or devices 1428 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 1432, which may be implemented by the machine readable instructions of FIG. 13, may be stored in the mass storage device 1428, in the volatile memory 1414, in the non-volatile memory 1416, and/or on at least one non-transitory computer readable storage medium such as a CD or DVD which may be removable.

From the foregoing, it will be appreciated that example systems, devices, apparatus, articles of manufacture, and methods have been disclosed for cooling electronic devices. Disclosed systems, apparatus, articles of manufacture, and methods improve the efficiency of using a computing device by enabling optimal performance of different heat generating components and preventing system performance degradation. Disclosed systems, apparatus, articles of manufacture, and methods are accordingly directed to one or more improvement(s) in the operation of a machine such as a computer or other electronic and/or mechanical device.

Examples disclosed herein exhibit many benefits with the design, assembly, and operation of electronic devices. Isolation of the heat generating components from thermal crosstalk leads to optimized thermal capability of the vapor chamber and the electronic device overall. Different sections of the vapor chamber using different types of wicks (e.g., advanced or simple) allows for cost optimization of the vapor chamber because different wick structures in the different sections leads enables the use of less complex wick structures in some sections rather than a complex advanced wick structure throughout the entire vapor chamber. Thermal optimization of the vapor chamber leads to lower air flow from the fans. The lower air flow from the fans leads to lower acoustic noise, which benefits end users from higher iso-acoustics performance. In addition, some sections of the vapor chamber can have only vacuum creating insulation over hot component for lower skin temperatures of the electronic device. Also, some sections of the vapor chamber may have solid material for simple (one phase) spreading of heat.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an ASIC) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as CPUs that may execute first instructions to perform one or more operations and/or functions, FPGAs that may be programmed with second instructions to cause configuration and/or structuring of the FPGAs to instantiate one or more operations and/or functions corresponding to the first instructions, GPUs that may execute first instructions to perform one or more operations and/or functions, DSPs that may execute first instructions to perform one or more operations and/or functions, XPUs, Network Processing Units (NPUs) one or more microcontrollers that may execute first instructions to perform one or more operations and/or functions and/or integrated circuits such as ASICs. For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example systems, apparatus, articles of manufacture, and methods related to multi-sectional vapor chambers for electronic devices are disclosed. Example 1 is a vapor chamber that includes a first panel; a second panel; and a wall extending between the first panel and the second panel to separate the vapor chamber into a first section and a second section between both the first panel and the second panel, the wall including insulation.

Example 2 includes the vapor chamber of Example 1, wherein the insulation includes an evacuated tube.

Example 3 includes the vapor chamber of any of Examples 1 or 2, wherein the first section has a first wicking structure and the second section has a second wicking structure different than the first wicking structure.

Example 4 includes the vapor chamber of any of Examples 1-3, wherein the first section has a first working fluid and the second section has a second working fluid different than the first working fluid.

Example 5 includes the vapor chamber of any of Examples 1-4, wherein the first panel and the second panel are metal and the wall is plastic.

Example 6 includes the vapor chamber of any of Examples 1-5, wherein the first section has a first wicking structure and a working fluid and the second section has a dry second wicking structure.

Example 7 includes the vapor chamber of Example 6, wherein the first wicking structure and the second wicking structure are different types of wicking structures.

Example 8 includes the vapor chamber of any of Examples 6 or 7, wherein the first section is to provide a first thermal cooling capability and the second section is to provide a second thermal cooling capability, the second thermal cooling capability different than the first thermal cooling capability.

Example 9 includes the vapor chamber of any of Examples 1-8, wherein the wall is a first wall, the vapor chamber further including a second wall coupled to the first wall, the second wall including the insulation, and the first wall and the second wall separating the vapor chamber into the first section, the second section, and a third section.

Example 10 includes the vapor chamber of any of Examples 1-9, wherein the first section has a first surface area and the second section has a second surface different than the first surface area.

Example 11 is an apparatus that includes a first vapor chamber; a second vapor chamber; and an insulation fence coupling the first vapor chamber to the second vapor chamber.

Example 12 includes the apparatus of Example 11, wherein the first vapor chamber is at a first height, and the second vapor chamber is at a second height different than the first height.

Example 13 includes the apparatus of Example 12, wherein the insulation fence includes a plurality of apertures to allow airflow from beneath the first vapor chamber to above the second vapor chamber.

Example 14 includes the apparatus of any of Examples 11-13, wherein the insulation fence inhibits thermal crosstalk between the first vapor chamber and the second vapor chamber.

Example 15 includes the apparatus of any of Examples 11-14, wherein the first vapor chamber has a first thickness and the second vapor chamber has a second thickness different than the first thickness.

Example 16 is an electronic device that includes a first heat generating component; a second heat generating component; and a multi-sectional vapor chamber including: a first section coupled to the first heating generating component; a second section coupled to the second heat generating component; and a thermal insulation wall separating the first section and the second section.

Example 17 includes the electronic device of Example 16, wherein the first section has a first cooling capacity and the second section has a second cooling capacity different than the first cooling capacity.

Example 18 includes the electronic device of any of Examples 16 or 17, wherein the first heat generating component is to consume a first amount of power and the second heat generating component is to consume a second amount of power different than the first amount of power.

Example 19 includes the electronic device of any of Examples 16-18, wherein the first heat generating component has a first temperature limit and the second heat generating component has a second temperature limit different than the first temperature limit.

Example 20 includes the electronic device of any of Examples 16-19, wherein the insulation wall is to impede heat exchange between the first section and the second section.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A vapor chamber for an electronic device, the vapor chamber comprising:
a first panel;
a second panel; and
a wall extending between the first panel and the second panel to separate the vapor chamber into a first section and a second section between the first panel and the second panel, the wall including insulation.

2. The vapor chamber of claim 1, wherein the insulation includes an evacuated tube.

3. The vapor chamber of claim 1, wherein the first section has a first wicking structure and the second section has a second wicking structure different than the first wicking structure.

4. The vapor chamber of claim 1, wherein the first section has a first working fluid and the second section has a second working fluid different than the first working fluid.

5. The vapor chamber of claim 1, wherein the first panel and the second panel are metal and the wall is plastic.

6. The vapor chamber of claim 1, wherein the first section has a first wicking structure and a working fluid and the second section has a dry second wicking structure.

7. The vapor chamber of claim 6, wherein the first wicking structure and the second wicking structure are different types of wicking structures.

8. The vapor chamber of claim 1, wherein the first section is to provide a first thermal cooling capability and the second section is to provide a second thermal cooling capability, the second thermal cooling capability different than the first thermal cooling capability.

9. The vapor chamber of claim 1, wherein the wall is a first wall, the vapor chamber further including a second wall coupled to the first wall, the second wall including the insulation, and the first wall and the second wall separating the vapor chamber into the first section, the second section, and a third section.

10. The vapor chamber of claim 1, wherein the first section has a first surface area and the second section has a second surface different than the first surface area.

11. An apparatus comprising:
a first vapor chamber;
a second vapor chamber; and
an insulation fence coupling the first vapor chamber to the second vapor chamber.

12. The apparatus of claim 11, wherein the first vapor chamber is at a first height, and the second vapor chamber is at a second height different than the first height.

13. The apparatus of claim 12, wherein the insulation fence includes a plurality of apertures to allow airflow from beneath the first vapor chamber to above the second vapor chamber.

14. The apparatus of claim 11, wherein the insulation fence inhibits thermal crosstalk between the first vapor chamber and the second vapor chamber.

15. The apparatus of claim 11, wherein the first vapor chamber has a first thickness and the second vapor chamber has a second thickness different than the first thickness.

16. An electronic device comprising:
a first heat generating component;
a second heat generating component; and
a multi-sectional vapor chamber including:
a first section coupled to the first heating generating component;
a second section coupled to the second heat generating component; and
a thermal insulation wall separating the first section and the second section.

17. The electronic device of claim 16, wherein the first section has a first cooling capacity and the second section has a second cooling capacity different than the first cooling capacity.

18. The electronic device of claim 16, wherein the first heat generating component is to consume a first amount of power and the second heat generating component is to consume a second amount of power different than the first amount of power.

19. The electronic device of claim 16, wherein the first heat generating component has a first temperature limit and the second heat generating component has a second temperature limit different than the first temperature limit.

20. The electronic device of claim 16, wherein the insulation wall is to impede heat exchange between the first section and the second section.
